(19) United States
(12) Patent Application Publication
(10) Pub. No.: US 2016/0240563 A1
(43) Pub. Date: Aug. 18, 2016

(54) SEMICONDUCTOR DEVICE AND METHOD OF FABRICATING THE SAME

(71) Applicants: ELECTRONICS AND TELECOMMUNICATIONS RESEARCH INSTITUTE, Daejeon (KR); Korea Advanced Institute of Science and Technology, Daejeon (KR)

(72) Inventors: Sang-Hee PARK, Daejeon (KR); Chi-Sun HWANG, Daejeon (KR); Min Ki RYU, Daejeon (KR); Jae-Eun PI, Daejeon (KR); Jong-Beom KO, Daejeon (KR); Hyein YEOM, Seoul (KR)

(21) Appl. No.: 15/043,402

(22) Filed: Feb. 12, 2016

(30) Foreign Application Priority Data
Feb. 13, 2015 (KR) 10-2015-0022573
Jan. 14, 2016 (KR) 10-2016-0004915

(51) Int. Cl. H01L 27/12; H01L 21/027; H01L 29/423; H01L 21/306; H01L 29/786; H01L 29/417

(52) U.S. Cl. CPC H01L 27/1225; H01L 27/127; H01L 29/7869; H01L 29/41733; H01L 29/42384; H01L 21/30604; H01L 21/0274

(57) ABSTRACT

Provided is a semiconductor device. The semiconductor device includes a second semiconductor pattern disposed on the substrate and configured to provide a channel region, and a first semiconductor pattern disposed between the substrate and the second semiconductor pattern, wherein the first semiconductor pattern includes a channel region that is a portion in contact with the second semiconductor pattern and source/drain regions that are portions exposed by the second semiconductor pattern.

### CROSS-REFERENCE TO RELATED APPLICATIONS

This U.S. non-provisional patent application claims priority under 35 U.S.C. §119 of Korean Patent Application Nos. 10-2015-0022573, filed on Feb. 13, 2015, and 10-2016-0004915, filed on Jan. 14, 2016, the entire contents of which are hereby incorporated by reference.

### BACKGROUND

The present disclosure herein relates to a semiconductor device and a method of fabricating the same, and more particularly, to a semiconductor device that includes a thin film transistor (TFT), and a method of fabricating the same.

Since a self-alignment type thin film transistor (TFT) may minimize the overlap capacitance between gate and source/drain electrodes and occupies a small area, it is being used for a high density display.

To simply describe a method of fabricating the TFT, an oxide semiconductor layer is formed on the substrate and then a gate insulating layer and a gate electrode are formed. In this case, the gate insulating layer is etched by the using of the gate electrode as an etching mask. The etching is typically performed through a dry etching process, which increases a process cost.

By the increasing of a carrier concentration through a doping process, the resistance of the oxide semiconductor layer that is exposed by the etching process decreases so that source/drain regions are formed. The doping process includes plasma processing, hydrogen ion doping using a nitride layer (SiNₓ), and the diffusion of dopants through the deposition of aluminum (Al) and the oxidation of the aluminum (Al). As such, the doping process may increase instability because in the following high temperature process, the dopants are diffused and thus parasitic capacitance may be generated.

### SUMMARY

The present disclosure provides a semiconductor device with higher stability and lower process costs.

The present disclosure also provides a method of fabricating the semiconductor device.

Tasks to be performed by the present disclosure are not limited to the above-mentioned tasks and other tasks not mentioned may be clearly understood by a person skilled in the art from the following descriptions.

An embodiment of the inventive concept provides a semiconductor device. The semiconductor device includes a substrate; a second semiconductor pattern disposed on the substrate and configured to provide a channel region; a first semiconductor pattern disposed between the substrate and the second semiconductor pattern, wherein the first semiconductor pattern includes a channel region that is a portion in contact with the second semiconductor pattern and source/drain regions that are portions exposed by the second semiconductor pattern; a gate insulating layer adjacent to at least one among the second semiconductor pattern and the first semiconductor pattern; and a gate electrode spaced apart from the first and second semiconductor patterns, with the gate insulating layer between the first and second semiconductor patterns and the gate electrode.

In an embodiments of the inventive concept, a method of fabricating a semiconductor device includes forming a gate electrode on a substrate; forming a gate insulating layer on the gate electrode; forming a first semiconductor pattern that covers a portion of the gate insulating layer and includes source/drain regions and a first channel region; and forming a second semiconductor pattern that includes a second channel region, on the first semiconductor pattern, wherein the second semiconductor pattern faces the gate electrode.

In an embodiments of the inventive concept, a method of fabricating a semiconductor device includes forming, on a substrate, a first semiconductor pattern that includes source/drain regions and a channel region between the source/drain regions, and a second thin film; sequentially forming an insulating layer and a conductive layer on the second thin film; and patterning the conductive layer, the insulating layer, and the second thin film to sequentially form a second semiconductor pattern, a gate insulating pattern, and a gate electrode on a first channel region of the first semiconductor pattern.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a cross-sectional view of a semiconductor device according to some embodiments of the inventive concept;

FIGS. 2A through 2E are cross-sectional views of a method of fabricating a semiconductor device according to some embodiments of the inventive concept;

FIG. 3 is a cross-sectional view of a semiconductor device according to some embodiments of the inventive concept; and

FIGS. 4A through 4D are cross-sectional views of a method of fabricating a semiconductor device according to some embodiments of the inventive concept.

### DETAILED DESCRIPTION

The objects, other objects, features and advantages of the inventive concept as described above would be easily understood through the following exemplary embodiments related to the accompanying drawings. However, the inventive concept is not limited to embodiments described herein but may also be embodied in other forms. Rather, the embodiments introduced herein are provided so that disclosed contents may be thorough and complete and the spirit of the inventive concept may be fully conveyed to a person skilled in the art. When the present disclosure mentions that a component are on another component, it means that the component may be formed directly on the other component or there may be a third component there between. Also, the thickness of components in the drawings is exaggerated for the effective description of technical content.

Embodiments in the present disclosure are described with reference to ideal, exemplary views of the inventive concept that are cross-sectional views and/or plan views. The thicknesses of layers and regions in the drawings are exaggerated for the effective description of technical content. Thus, the forms of exemplary views may vary depending on fabrication technologies and/or tolerances. Thus, embodiments of the present disclosure are not limited to shown specific forms and also include variations in form produced according to manufacturing processes. For example, an etch region shown in a rectangular shape may have a round shape or a shape having a certain curvature. Thus, regions illustrated in the drawings have attributes and the shapes of the regions illustrated in the drawings are intended to illustrate the specific shapes of the regions of elements and not to limit the scope of the inventive concept. Although the terms first, second, third, etc. are used in various embodiments of the present disclosure in order to describe various components, these components are not limited by these terms. These terms are only used in order to distinguish a component from another. Embodiments that are described and illustrated herein also include their complementary embodiments.

The terms used herein are only for explaining embodiments, not limiting the inventive concept. The terms in a singular form in the disclosure also include plural forms unless otherwise specified. The term ‘comprises’ and/or ‘comprising’ used in the disclosure does not exclude the existence or addition of one or more other components.

Various embodiments are described below in detail with reference to the accompanying drawings.

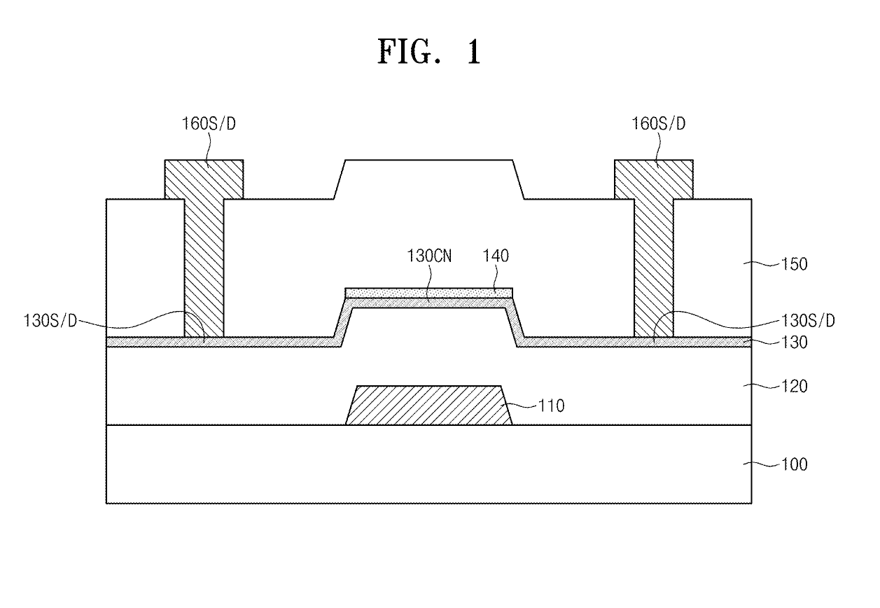

FIG. 1 is a cross-sectional view of a semiconductor device according to some embodiments of the inventive concept.

Referring to FIG. 1, the semiconductor device may include a substrate 100, a gate electrode 110, a gate insulating layer 120, a first semiconductor pattern 130, a second semiconductor pattern 140 and source/drain electrodes 160S/D.

The substrate 100 may include at least one among glass, plastic, paper, fiber, and metal foil coated with an insulating layer.

The gate electrode 110 is disposed on the substrate 100 and the gate electrode 110 may include chrome (Cr), aluminum (Al), molybdenum (Mo), tantalum (Ta), titanium (Ti) or alloy thereof. Although not shown in detail, the gate electrode 110 may have a multi-layered structure.

The gate insulating layer 120 may cover the gate electrode 110. The gate insulating layer 120 may include SiOₓ.

The first semiconductor pattern 130 may cover at least a portion of the gate insulating layer 120. According to an embodiment of the inventive concept, the first semiconductor pattern 130 may include the source/drain regions 130S/D and a first channel region 130CN. The first channel region 130CN may be provided at the central part of the first semiconductor pattern 130 and the source/drain regions 130S/D may be provided at both ends of the first channel region 130CN. The source/drain regions 130S/D of the first semiconductor pattern 130 are in electrical contact with the source/drain electrodes, respectively to function as a conductor. The first semiconductor pattern 130 may include an oxide semiconductor. The first semiconductor pattern 130 may include at least one selected from a group that consists of e.g., In₂O₃, ZnSnO, InZnSnO, aluminum (Al) doped InZnSnO, indium tin oxide (ITO), and indium zinc oxide (IZO).

The second semiconductor pattern 140 may cover the first channel region 130CN of the first semiconductor pattern 130. According to an embodiment, the second semiconductor pattern 140 may be disposed at a position where it faces the first channel region 130CN of the first semiconductor pattern 130 and the gate electrode 110 under the gate insulating layer 120. The width of the second semiconductor pattern 140 may be substantially the same as that of the gate electrode 110. The second semiconductor pattern 140 may be provided as a second channel region. The first channel region 130CN of the first semiconductor pattern 130 and the second semiconductor pattern 140 may be in contact with each other. The first channel region 130CN and the second channel may be provided as channels of a thin film transistor (TFT). The second semiconductor pattern 140 may include an oxide semiconductor. The second semiconductor pattern 140 may include at least one selected from a group that consists of e.g., InGaZnO, aluminum (Al) doped ZnSnO and HfInZnO.

According to an embodiment of the inventive concept, the first semiconductor pattern 130 may be made up of a conductor that is in contact with the source/drain electrodes 160S/D, and the second semiconductor pattern 140 may be provided as a channel region between the source/drain electrodes 160S/D. To this end, the carrier concentration of the first semiconductor pattern 130 may be higher than the carrier concentration of the second semiconductor pattern 140 and the first semiconductor pattern may have a concentration that is equal to or higher than about 10¹⁸ cm⁻³. For example, in the case where the first semiconductor pattern 130 and the second semiconductor pattern 140 include ITO, it is possible to adjust a composition ratio between materials within the first semiconductor pattern 130 and the second semiconductor pattern 140 to adjust carrier concentrations within the first semiconductor pattern 130 and the second semiconductor pattern 140. For example, it is possible to increase an amount of tin (Sn) within the second semiconductor pattern 140 so that it is more than an amount of tin (Sn) within the first semiconductor pattern 130 or increase oxygen partial pressure during the forming of the first semiconductor pattern 130 to adjust the carrier concentrations. In the case where the same material is included as above, e.g., where deposition is performed through a plasma enhanced atomic layer deposition (PEALD) process, the first semiconductor pattern 130 may use water as the precursor of oxygen and the second semiconductor pattern 140 may use oxygen plasma or adjust the concentration of an element within a material so that it is possible to adjust the carrier concentrations within the first semiconductor pattern 130 and the second semiconductor pattern 140. Alternatively, it is possible to form the first semiconductor pattern 130 and the second semiconductor pattern 140 with different materials to adjust the carrier concentrations within the first semiconductor pattern 130 and the second semiconductor pattern 140. For example, the first semiconductor pattern 130 may be formed of a material that has many carriers and the second semiconductor pattern 140 may be formed of a material that has a few carriers.

When the first channel region 130CN of the first semiconductor pattern 130 that has a high-concentration carrier is in contact with the second semiconductor pattern 140 that has a low-concentration carrier, a carrier transfer from the first channel region 130CN of the first semiconductor pattern 130 to the second semiconductor pattern 140 occurs, thus the first channel region 130CN of the first semiconductor pattern 130 may function as a channel.

The first semiconductor pattern 130 and the second semiconductor pattern 140 may be formed of materials that have different etch selectivity by an etchant used for wet etching. For example, due to the etchant, the etching speed of the second semiconductor pattern 140 is quicker than that of the first semiconductor pattern 130, and while the second semiconductor pattern 140 is etched, the first semiconductor pattern 130 may not be substantially etched.

As described above, since without doping the first semiconductor pattern 130 and the second semiconductor pattern 140 with dopant, materials within the first semiconductor pattern 130 and the second semiconductor pattern 140 are adjusted to define the source/drain regions 130S/D and the channel region, it is possible to prevent limitations due to the diffusion of dopant.

An interlayer insulating layer 150 may be provided which covers the first semiconductor pattern 130 and the second semiconductor pattern 140. The interlayer insulting layer 150 may include at least one among SiOₓ, SiNₓ, and SiON. The interlayer insulating layer 150 may include contact holes that expose the source/drain regions 130S/D of the first semiconductor pattern 130.

The source/drain electrodes 160S/D may be provided to fill the contact holes, respectively. The source/drain electrodes 160S/D may be in contact with the source/drain regions 130S/D of the first semiconductor pattern 130, respectively. Each of the source/drain electrodes 160S/D may include at least one among chrome (Cr), aluminum (Al), molybdenum (Mo), tantalum (Ta), titanium (Ti) or alloy thereof.

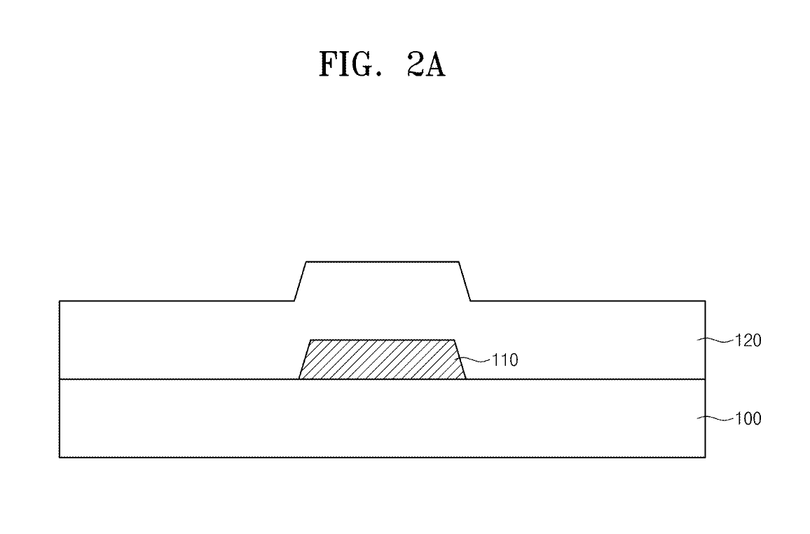

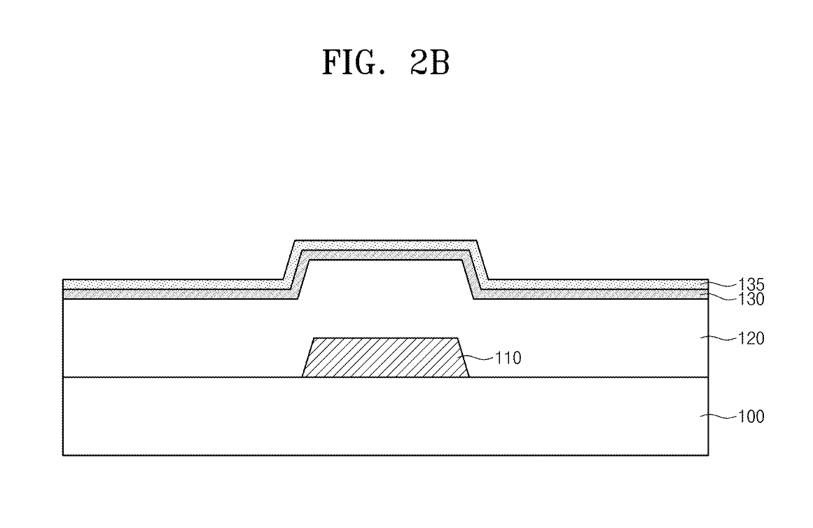

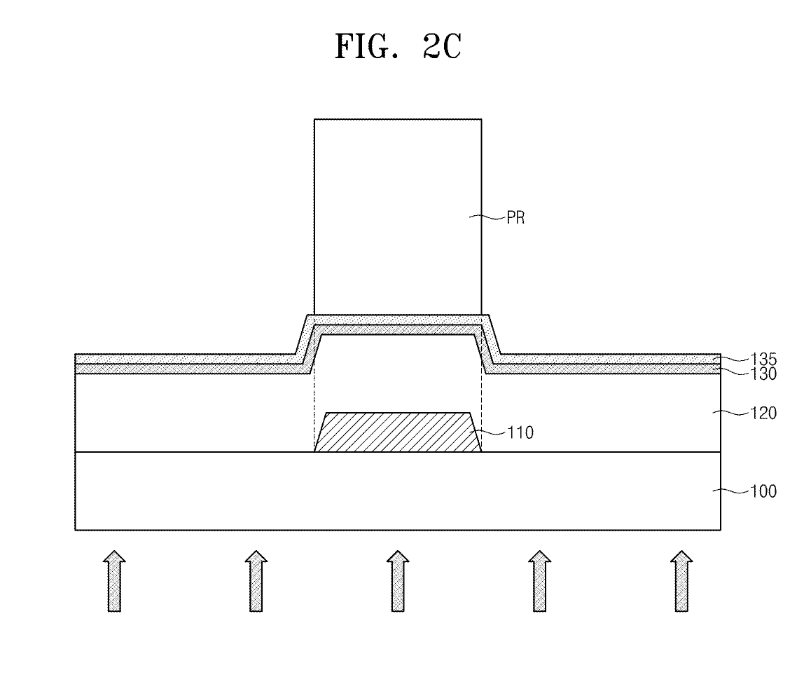

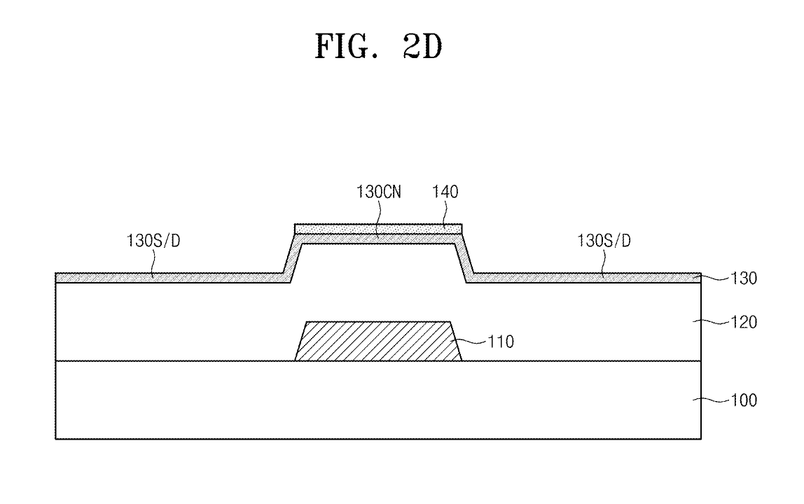

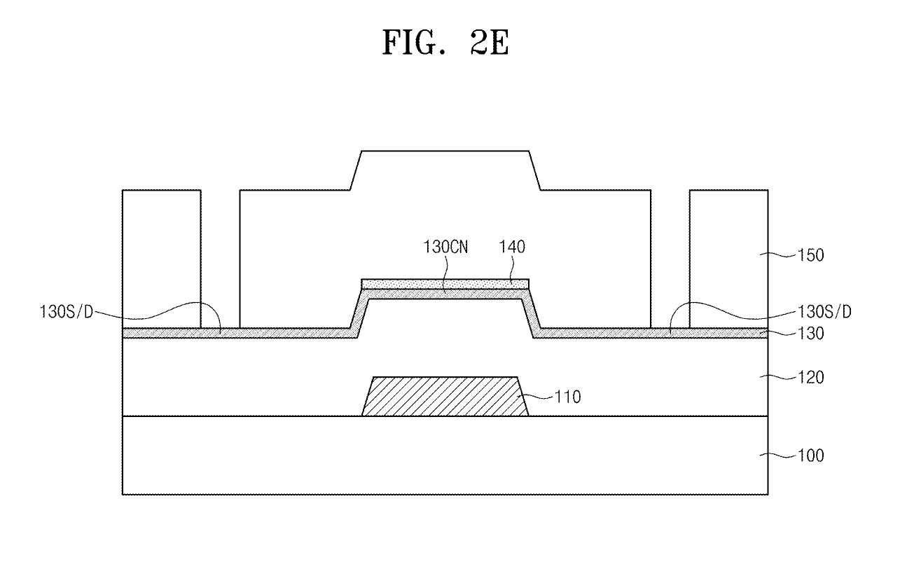

FIGS. 2A through 2E are cross-sectional views of a method of fabricating a semiconductor device according to some embodiments of the inventive concept.

Referring to FIG. 2A, it is possible to form and then pattern a first conductive layer (not shown) on a substrate 100 to form a gate electrode 110. The first conductive layer may include at least one among chrome (Cr), aluminum (Al), molybdenum (Mo), tantalum (Ta), titanium (Ti) or alloy thereof. It is possible to form a gate insulating layer that covers the gate electrode 110, on the substrate 100 on which the gate electrode 110 has been formed. The gate insulating layer 120 may include silicon oxide.

Referring to FIG. 2B, it is possible to sequentially form a first semiconductor pattern 130 and a second semiconductor pattern 140 on the gate insulating layer 120.

According to some embodiments, it is possible to form the first semiconductor pattern 130 on the gate insulating layer 120. The first semiconductor pattern 130 may include carriers that have a first concentration (e.g., a concentration equal to higher than about 10¹⁸ cm⁻³). For example, the first semiconductor pattern may include at least one selected from a group that consists of In₂O₃, ZnSnO, InZnSnO, aluminum (Al) doped InZnSnO, ITO, and IZO. The first semiconductor pattern 130 may cover the gate electrode 110 under the gate insulating layer 120 and extend to both ends of the gate electrode 110.

It is possible to form a second thin film 135 on the first semiconductor pattern 130. The second thin film 135 may include carriers that have a second concentration lower than the first concentration (e.g., a concentration lower than or equal to about 10¹⁸ cm⁻³). For example, the second thin film 135 may include at least one selected from a group that consists of InGaZnO, aluminum (Al) doped ZnSnO and HfInZnO.

Referring to FIGS. 2C and 2D, it is possible to form a photo-resist layer on the second thin film 135 and perform a photolithography process on the photo-resist towards the rear of the substrate 100, in which case it is possible to use the gate electrode 110 as a photo mask to perform photolithography on a portion not covered by the gate electrode 110 to form a photo-resist pattern PR. It is possible to remove the second thin film 135 not covered by the photo-resist pattern PR at both sides of the gate electrode 110 to form a second semiconductor pattern 140 at a position where the second semiconductor pattern faces the gate electrode 110. An etchant used for the wet etching may not substantially etch the first semiconductor pattern 130 and may include a material having etch selectivity that selectively etches the exposed second thin film 135.

When the central part 130CN of the first semiconductor pattern 130 that has a high-concentration carrier is in contact with the second semiconductor pattern 140 that has a low-concentration carrier, a carrier transfer from the central part 130CN of the first semiconductor pattern 130 to the second semiconductor pattern 140 occurs, thus the central part 130CN of the first semiconductor pattern 130 may function as a channel. The second semiconductor pattern 140 may be disposed to be in contact with the central part 130CN of the first semiconductor pattern 130. The second semiconductor pattern 140 may function as a second channel region and may function as a channel of a subsequently completed TFT along with the central part 130CN.

Since the second semiconductor pattern 140 uses the second thin film 135 as a photo mask, it may have a structure that is self-aligned with the gate electrode 110.

Referring to FIG. 2E, it is possible to form an interlayer insulating layer 150 on the first semiconductor pattern 130 and the second semiconductor pattern 140. The interlayer insulating layer 150 may include at least one among silicon oxide, silicon nitride or silicon oxynitride.

It is possible to etch the interlayer insulating layer 150 to form contact holes (not shown) that expose the source/drain regions 130S/D of the first semiconductor pattern 130.

Referring back to FIG. 1, it is possible to form source/drain electrodes 160S/D that fill the contact holes, respectively. A second conductive layer that fills the contact hole may be formed on the interlay insulating layer 150 and then the second conductive layer may be patterned so that the source/drain electrodes 160S/D may be formed. The source/drain electrodes 160S/D may be in contact with the source/drain regions 130S/D of the first semiconductor pattern 130, respectively. Also, the source/drain electrodes 160S/D may have respective structures that protrude from the interlayer insulating layer 150.

Accordingly, it is possible to complete a TFT that includes the first semiconductor pattern 130, the second semiconductor pattern 140, the gate insulating layer 120, the gate electrode 110, and the source/drain electrodes 160S/D.

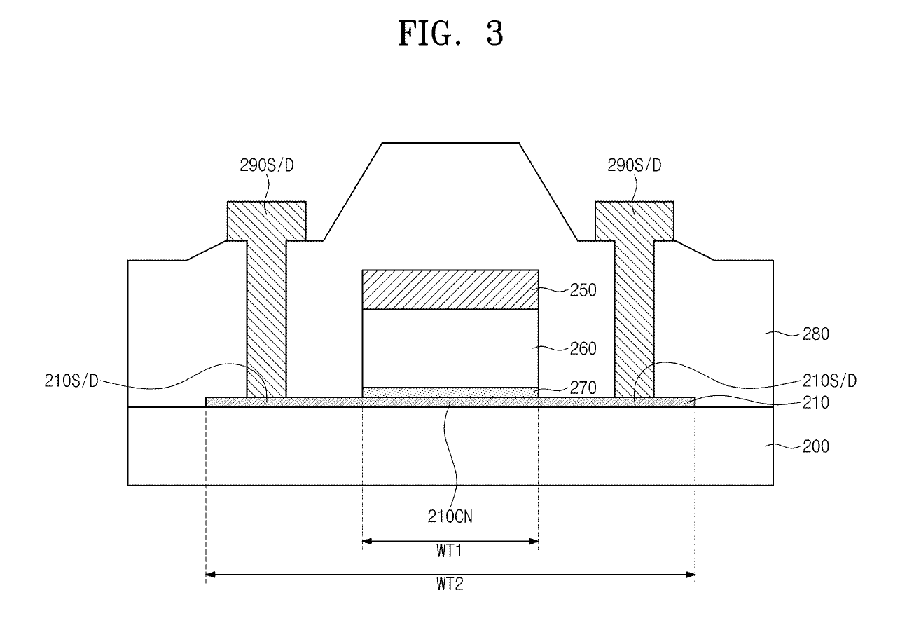

FIG. 3 is a cross-sectional view of a semiconductor device according to some embodiments of the inventive concept.

Referring to FIG. 3, the semiconductor device may include a substrate 200, a gate insulating pattern 260, a second semiconductor pattern 210, a first semiconductor pattern 270, a gate electrode 250, and source/drain electrodes 290S/D.

The substrate 200 may include at least one among glass, plastic, paper, fiber, and metal foil coated with an insulating layer.

The second semiconductor pattern 210 may cover a portion of the substrate 200. The first semiconductor pattern 210 may include a first channel region 210CN that is provided at its central portion, and source/drain regions 210S/D that are provided at both ends of the first channel region 210CN. The source/drain regions 210S/D of the first semiconductor pattern 210 are in electrical contact with the source/drain electrodes 290S/D, respectively to function as a conductor. The first semiconductor pattern 210 may include an oxide semiconductor. The first semiconductor pattern 210 may include at least one selected from a group that consists of e.g., In₂O₃, ZnSnO, InZnSnO, aluminum (Al) doped InZnSnO, indium tin oxide (ITO), indium zinc oxide (IZO), and aluminum (Al) doped ZnO.

The second semiconductor pattern 270 may cover the first channel region 210CN of the first semiconductor pattern 210. The source/drain regions 210S/D of the first semiconductor pattern 210 may be exposed by the second semiconductor pattern 270. The second semiconductor pattern 270 is provided as a second channel region. The second semiconductor pattern 270 may include an oxide semiconductor. The second semiconductor pattern 270 may include at least one selected from a group that consists of e.g., InGaZnO, aluminum (Al) doped ZnSnO and HfInZnO.

The second semiconductor pattern 270 has a first width WT1. The first semiconductor pattern 210 may have a second width WT2 that is wider than the first width WT1.

The gate insulating pattern 260 and the gate electrode 250 may be sequentially stacked on the second semiconductor pattern 270. Each of the gate insulating pattern 260 and the gate electrode 250 may have the first width WT1. Thus, the source/drain regions 210S/D of the first semiconductor pattern 210 may be exposed by the second semiconductor pattern 270, the gate insulating pattern 260, and the gate electrode 250.

The interlayer insulating layer 280 covers the first semiconductor pattern 210, the second semiconductor pattern 270, the gate insulating pattern and the gate electrode 250 and may include contact holes that expose the upper surfaces of the source/drain regions 210S/D of the first semiconductor pattern 210.

The source/drain electrodes 290S/D may be provided to fill the contact holes, respectively. The source/drain electrodes 290S/D may be in contact with the source/drain regions 210S/D of the first semiconductor pattern 210, respectively.

Other components excluding the above-described components are similar to those in FIG. 1 and thus omitted.

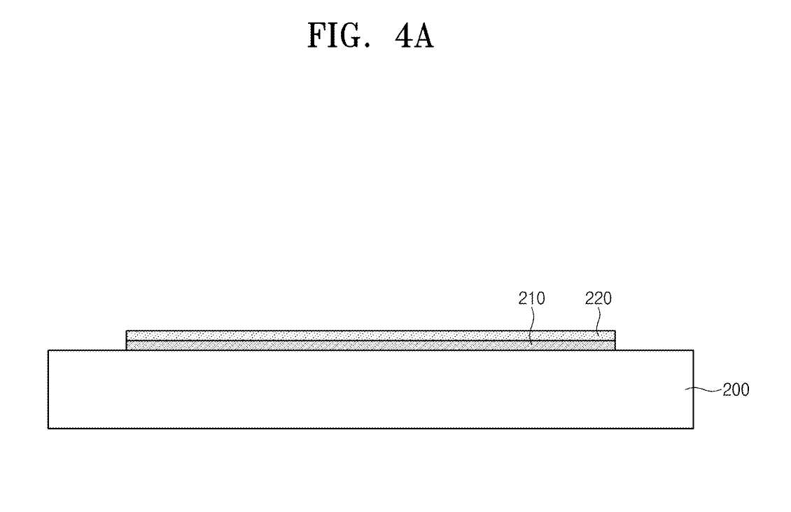

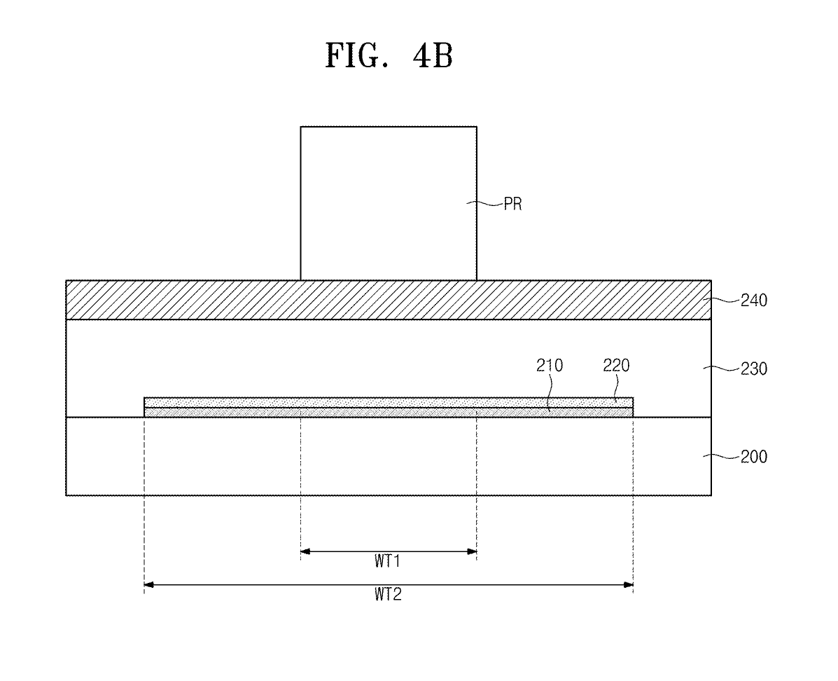

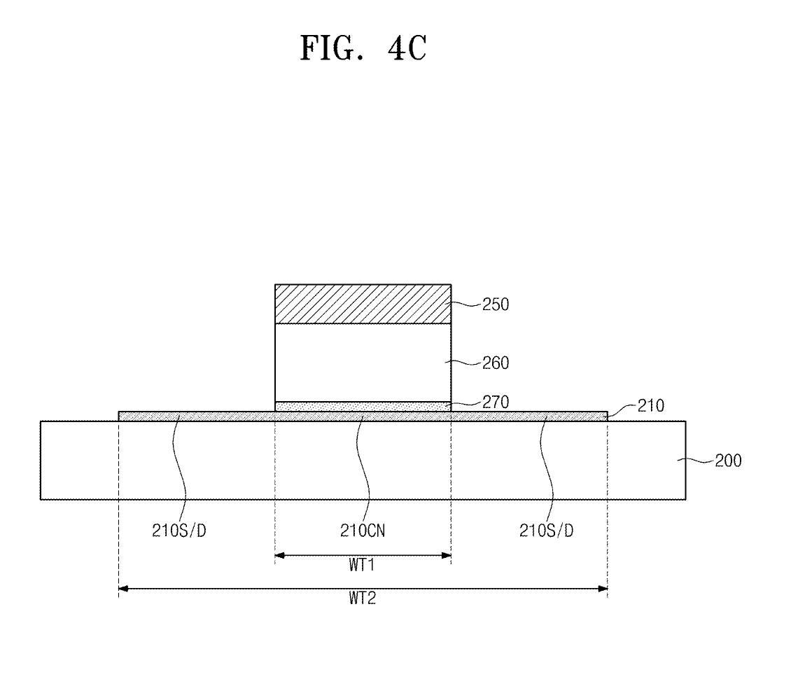

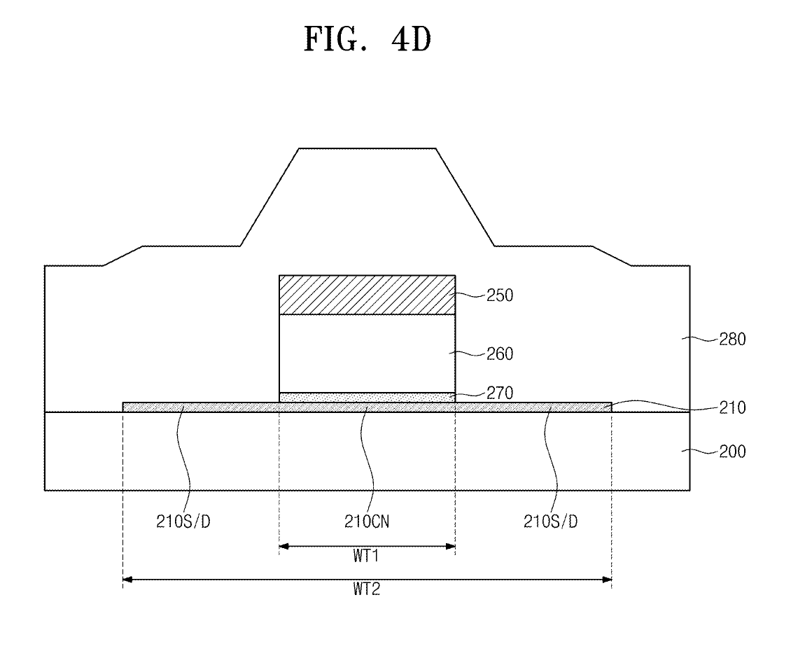

FIGS. 4A through 4D are cross-sectional views of a method of fabricating a semiconductor device according to some embodiments of the inventive concept.

Referring to FIG. 4A, it is possible to form a first semiconductor pattern 210 on a substrate 200. The first semiconductor pattern 210 may include carriers that have a first concentration (e.g., a concentration equal to or higher than about 10¹⁸ cm⁻³). For example, the first semiconductor pattern 210 may include at least one selected from a group that consists of In₂O₃, ZnSnO, InZnSnO, aluminum (Al) doped InZnSnO, ITO, and IZO.

It is possible to form a second thin film 220 on the first semiconductor pattern 210. The second thin film may include a carrier that has a second concentration (e.g., a concentration lower than or equal to about 10¹⁸ cm⁻³). For example, the first thin film may include at least one selected from a group that consists of InGaZnO, aluminum (Al) doped ZnSnO and HfInZnO.

The first semiconductor pattern 210 may include source/drain regions 210S/D and a first channel region 210CN that is disposed between the source/drain regions 210S/D.

Referring to FIG. 4B, it is possible to sequentially form a gate insulating layer 230 and a first conductive layer 240 on the second thin film 220. The gate insulating layer 230 may include silicon oxide. The first conductive layer 240 may include at least one among chrome (Cr), aluminum (Al), molybdenum (Mo), tantalum (Ta), titanium (Ti) or alloy thereof.

Referring to FIG. 4C, after forming a photo-resist pattern PR on the first conductive layer 240, it is possible to use the photo-resist pattern PR as an etching mask to etch the first conductive layer 240, the gate insulating layer 230, and the second thin film 220 to form a gate electrode 250, a gate insulating pattern 260, and a second semiconductor pattern 270. The widths of the gate electrode 250, the gate insulating pattern and the second semiconductor pattern 270 may be substantially the same. The second semiconductor pattern 270 may be provided to be in contact with the first channel region 210CN of the first semiconductor pattern 210. Optionally, the photo-resist pattern PR may be removed.

Referring to FIG. 4D, it is possible to form an interlayer insulating layer 280 on the substrate 200 on which the first semiconductor pattern 210, the second semiconductor pattern 270, the gate insulating pattern 260, and the gate electrode 250 are formed.

Referring back to FIG. 3, it is possible to pattern the interlayer insulating layer 280 to form contact holes (not shown) that expose the source/drain regions 210S/D of the first semiconductor pattern 210. It is possible to fill the contact holes with a second conductive layer to form source/drain electrodes 290S/D that are electrically connected to the source/drain regions 210S/D, respectively.

Other components excluding the above-described components are similar to those in FIGS. 2A through 2E and thus omitted.

According to embodiments of the inventive concept, a channel region may have a multi-layered structure due to a first semiconductor pattern that is made up of a thin film that includes high-density carriers, and a second semiconductor pattern that is made up of a thin film that includes low-density carriers. Since it is possible to provide the first semiconductor pattern with source/drain regions without doping dopant, it is possible to prevent problems that occur in the doping process.

Also, since the first semiconductor pattern and the second semiconductor pattern include materials that have etching selectivity, it is possible to use wet etching to etch the second semiconductor pattern.

While embodiments of the inventive concept are described with reference to the accompanying drawings, a person skilled in the art may understand that the inventive concept may be practiced in other particular forms without changing technical spirits or essential characteristics. Therefore, embodiments described above should be understood as illustrative and not limitative in every aspect.

What is claimed is:

1. A semiconductor device comprising:
a substrate;
a second semiconductor pattern disposed on the substrate and configured to provide a channel region;
a first semiconductor pattern disposed between the substrate and the second semiconductor pattern, wherein the first semiconductor pattern includes a channel region that is a portion in contact with the second semiconductor pattern and source/drain regions that are portions exposed by the second semiconductor pattern;
a gate insulating layer adjacent to at least one among the second semiconductor pattern and the first semiconductor pattern; and
a gate electrode spaced apart from the first and second semiconductor patterns, with the gate insulating layer between the first and second semiconductor patterns and the gate electrode.

2. The semiconductor device of claim 1, wherein the gate electrode is in contact with the substrate, and
the gate insulating layer is disposed between the gate electrode and the first semiconductor pattern.

3. The semiconductor device of claim 1, wherein the first semiconductor pattern is in contact with the substrate, and
the second semiconductor pattern, the gate insulating layer, and the gate electrode are sequentially disposed on the first semiconductor pattern.

4. The semiconductor device of claim 1, wherein carriers in the first semiconductor pattern have a first concentration, and
carriers in the second semiconductor pattern have a second concentration that is lower than the first concentration.

5. The semiconductor device of claim 4, wherein the first concentration is equal to or higher than about 10¹⁸ cm⁻³, and the second concentration is lower than or equal to about 10¹⁸ cm⁻³.

6. The semiconductor device of claim 1, wherein the second semiconductor pattern comprises at least one selected from a group that consists of InGaZnO, aluminum (Al) doped ZnSnO, and HfInZnO.

7. The semiconductor device of claim 1, wherein the first semiconductor pattern comprises at least one selected from a group that consists of In₂O₃, ZnSnO, InZnSnO, aluminum (Al) doped InZnSnO, indium tin oxide (ITO), indium zinc oxide (IZO), and aluminum (Al) doped ZnO.

8. The semiconductor device of claim 1, further comprising source/drain electrodes that are in contact with the source/drain regions, respectively.

9. A method of fabricating a semiconductor device, the method comprising:
forming a gate electrode on a substrate;
forming a gate insulating layer on the gate electrode;
forming a first semiconductor pattern that covers a portion of the gate insulating layer and includes source/drain regions and a first channel region; and
forming a second semiconductor pattern that includes a second channel region, on the first semiconductor pattern, wherein the second semiconductor pattern corresponds to the gate electrode.

10. The method of claim 9, wherein the forming of the second semiconductor pattern comprises:
forming a second thin film and a photo-resist layer on the gate insulating layer on which the first semiconductor pattern is formed;
performing a photolithography process towards a rear of the substrate to use the gate electrode as a photo mask on a photo-resist layer exposed by the gate electrode to form a photo-resist pattern; and
wet etching the second thin film using the photo-resist pattern as an etching mask.

11. The method of claim 10, wherein the first semiconductor pattern is not etched while the second thin film is etched.

12. The method of claim 9, wherein carriers in the first semiconductor pattern have a first concentration, and
carriers in the second semiconductor pattern have a second concentration that is lower than the first concentration.

13. The method of claim 12, wherein the first concentration is equal to or higher than about 10¹⁸ cm⁻³, and
the second concentration is lower than or equal to about 10¹⁸ cm⁻³.

14. The method of claim 9, wherein the first semiconductor pattern comprises at least one selected from a group that consists of In₂O₃, ZnSnO, InZnSnO, aluminum (Al) doped InZnSnO, indium tin oxide (ITO), indium zinc oxide (IZO), and aluminum (Al) doped ZnO.

15. The method of claim 9, wherein the second semiconductor pattern comprises at least one selected from a group that consists of InGaZnO, aluminum (Al) doped ZnSnO, and HfInZnO.

16. The method of claim 9, further comprising forming source/drain electrodes that are electrically connected to the source/drain regions, respectively.

17. A method of fabricating a semiconductor device, the method comprising:
forming, on a substrate, a first semiconductor pattern that comprises source/drain regions and a channel region between the source/drain regions, and a second thin film;
sequentially forming an insulating layer and a conductive layer on the second thin film; and
patterning the conductive layer, the insulating layer, and the second thin film to sequentially form a second semiconductor pattern, a gate insulating pattern, and a gate electrode on a first channel region of the first semiconductor pattern.

18. The method of claim 17, wherein carriers in the first semiconductor pattern have a first concentration, and
carriers in the second semiconductor pattern have a second concentration that is lower than the first concentration.

19. The method of claim 18, wherein the first concentration is equal to or higher than about 10¹⁸ cm⁻³, and
the second concentration is lower than or equal to about 10¹⁸ cm⁻³.

20. The method of claim 17, wherein the first semiconductor pattern comprises at least one selected from a group that consists of In₂O₃, ZnSnO, InZnSnO, aluminum (Al) doped InZnSnO, indium tin oxide (ITO), indium zinc oxide (IZO), and aluminum (Al) doped ZnO, and the second semiconductor pattern comprises at least one selected from a group that consists of InGaZnO, aluminum (Al) doped ZnSnO, and HfInZnO.
